(19) United States
(12) Patent Application Publication
(10) Pub. No.: US 2022/0347778 A1
(43) Pub. Date: Nov. 3, 2022

(54) Laser Printing of Solder Pastes

(71) Applicant: Orbotech Ltd., Yavne (IL)

(72) Inventors: Jonathan ANKRI, Modiin (IL); Zvi KOTLER, Tel Aviv (IL)

(21) Appl. No.: 17/422,169

(22) PCT Filed: Mar. 17, 2021
(86) PCT No.: PCT/IB2021/052239

§ 371 Date: Jul. 9, 2021

Related U.S. Application Data
(60) Provisional application No. 63/045,111, filed on Jun. 28, 2020.

(51) Int. Cl. B23K 1/005; H05K 3/12; H05K 3/34; B23K 26/0622; B23K 26/40; B23K 26/06; B23K 1/00

(52) U.S. Cl. CPC B23K 1/0056; H05K 3/1275; H05K 3/3485; B23K 26/0622; B23K 26/40; B23K 26/0604; B23K 1/0016; H05K 2203/107; B23K 2103/42

(57) ABSTRACT

A method for fabrication includes providing a donor sheet, including a donor substrate, which is transparent in a specified spectral range, a sacrificial layer, which absorbs optical radiation within the specified spectral range and is disposed over the donor substrate, and a donor film, which includes a paste and is disposed over the sacrificial layer. The donor sheet is positioned so that the donor film is in proximity to a target location on an acceptor substrate. A pulsed laser beam impinges on the sacrificial layer with a pulse energy and spot size selected so as to ablate the sacrificial layer, thus causing a viscoelastic jet of the paste to be ejected from the donor film and to deposit, at the target location on the acceptor substrate, a dot having a diameter less than the spot size of the laser beam.

### CROSS-REFERENCE TO RELATED APPLICATIONS

This application claims priority to the provisional patent application filed Jun. 28, 2020 and assigned U.S. App. No. 63/045,111, the disclosure of which is hereby incorporated by reference.

### FIELD OF THE INVENTION

The present invention relates generally to fabrication of electronic devices, and particularly to methods and systems for soldering.

### BACKGROUND

In laser direct-write (LDW) techniques, a laser beam is used to create a patterned surface with spatially-resolved three-dimensional structures by controlled material ablation or deposition. Laser-induced forward transfer (LIFT) is an LDW technique that can be applied in depositing micro-patterns on a surface.

In LIFT, laser photons provide the driving force to catapult a small volume of material from a donor film toward an acceptor substrate. Typically, the laser beam interacts with the inner side of the donor film, which is coated onto a non-absorbing carrier substrate. The incident laser beam, in other words, propagates through the transparent carrier substrate before the photons are absorbed by the inner surface of the film. Above a certain energy threshold, material is ejected from the donor film toward the surface of the acceptor substrate. Given a proper choice of donor film and laser beam pulse parameters, the laser pulses cause molten droplets of the donor material to be ejected from the film, and then to land and harden on the acceptor substrate.

LIFT systems are particularly (though not exclusively) useful in printing conductive metal droplets and traces for purposes of electronic circuit fabrication. A LIFT system of this sort is described, for example, in U.S. Pat. No. 9,925,797, whose disclosure is incorporated herein by reference. This patent describes printing apparatus, including a donor supply assembly, which is configured to provide a transparent donor substrate having opposing first and second surfaces and a donor film formed on the second surface so as to position the donor film in proximity to a target area on an acceptor substrate. An optical assembly is configured to direct multiple output beams of laser radiation simultaneously in a predefined spatial pattern to pass through the first surface of the donor substrate and impinge on the donor film so as to induce ejection of material from the donor film onto the acceptor substrate according, thereby writing the predefined pattern onto the target area of the acceptor substrate.

LIFT has also been used experimentally in printing solder pastes, which are suspensions of metal solder particles in a highly-viscous medium, known as a flux. LIFT-based techniques of this sort are described, for example, by Mathews et al., in “Laser forward transfer of solder paste for microelectronics fabrication,” Proc. SPIE 9351, Laser-based Micro- and Nanoprocessing IX, 93510Y (March 2015). The authors describe transfer, patterning, and subsequent reflow of commercial Pb-free solder pastes using LIFT, both with the donor substrate in contact with the receiving substrate and across a 25 μm gap, including transfer of solder paste features down to 25 μm in diameter and as large as a few hundred microns.

### SUMMARY

Embodiments of the present invention that are described hereinbelow provide improved methods and system for fabrication of electrical circuits and devices.

There is therefore provided, in accordance with an embodiment of the invention, a method for fabrication, which includes providing a donor sheet including a donor substrate, which is transparent in a specified spectral range and has opposing first and second surfaces, a sacrificial layer, which absorbs optical radiation within the specified spectral range and is disposed over the first surface of the donor substrate, and a donor film, which includes a paste and is disposed over the sacrificial layer on the donor substrate. The donor sheet is positioned so that the donor film is in proximity to a target location on an acceptor substrate. A pulsed laser beam in the specified spectral range is directed to pass through the second surface of the donor substrate and impinge on the sacrificial layer with a pulse energy and spot size selected so as to ablate the sacrificial layer, thus causing a viscoelastic jet of the paste to be ejected from the donor film and to deposit, at the target location on the acceptor substrate, a dot having a diameter less than the spot size of the laser beam.

In a disclosed embodiment, the donor substrate includes a polymer foil. Typically, the polymer foil has a thermal conductivity κ<0.5 W/m*K.

Additionally or alternatively, the sacrificial layer includes a metal film. In one embodiment, the donor sheet includes a polymeric protective layer between the metal film and the donor film. Further additionally or alternatively, the metal film has a thickness less than 100 nm and includes a metal selected from a group consisting of titanium, tungsten, chromium and molybdenum.

In a disclosed embodiment, the paste is a solder paste, which may include metal particles having a diameter greater than 10 μm. The diameter of the dot formed by the viscoelastic jet can be less than 200 μm.

In some embodiments, positioning the donor sheet includes holding the donor film at a distance of at least 200 μm from a surface of the acceptor substrate, or even at a distance that is at least 500 μm.

In a disclosed embodiment, directing the pulsed laser beam includes directing infrared laser radiation to impinge on the sacrificial layer. Additionally or alternatively, directing the pulsed laser beam includes directing one or more pulses to impinge on the sacrificial layer with an energy greater than 200 μJ per pulse, wherein the one or more pulses have a duration between 10 ns and 5 μs per pulse.

Further additionally or alternatively, the spot size of the laser beam impinging on the sacrificial layer is greater than 200 μm, or even greater than 300 μm, and the diameter of the dot deposited by the viscoelastic jet is less than 200 μm.

In some embodiments, directing the pulsed laser beam includes directing an array of pulsed laser beams to impinge simultaneously at respective points on the sacrificial layer, so as to deposit a corresponding matrix of dots on the acceptor substrate. In one embodiment, directing the array of pulsed laser beams includes depositing a first matrix of the dots on the acceptor substrate, and then shifting the donor sheet and directing the array of the pulsed laser beams to deposit a second matrix of the dots, interleaved with the first matrix of the dots on the acceptor substrate.

There is also provided, in accordance with an embodiment of the invention, apparatus for fabrication, including a donor sheet, which includes a donor substrate, which is transparent in a specified spectral range and has opposing first and second surfaces, a sacrificial layer, which absorbs optical radiation within the specified spectral range and is disposed over the first surface of the donor substrate, and a donor film, which includes a paste and is disposed over the sacrificial layer on the donor substrate. The donor sheet is positioned so that the donor film is in proximity to a target location on an acceptor substrate. A laser is configured to output a pulsed laser beam in the specified spectral range. An optical assembly is configured to direct the pulsed laser beam to pass through the second surface of the donor substrate and impinge on the sacrificial layer with a pulse energy and spot size selected so as to ablate the sacrificial layer, thus causing a viscoelastic jet of the paste to be ejected from the donor film and to deposit, at the target location on the acceptor substrate, a dot having a diameter less than the spot size of the laser beam.

The present invention will be more fully understood from the following detailed description of the embodiments thereof, taken together with the drawings in which:

### BRIEF DESCRIPTION OF THE DRAWINGS

FIG. 1 is a schematic pictorial illustration of a system for LIFT printing of solder pastes, in accordance with an embodiment of the invention;

FIG. 2A is a schematic sectional view of a jet of solder paste ejected from a donor film onto an acceptor substrate in a LIFT process, in accordance with an embodiment of the invention;

FIG. 2B is a schematic sectional view of a dot of solder paste deposited on the acceptor substrate by the jet of FIG. 2A;

FIG. 3 is a photomicrograph showing dots of solder paste deposited on metal pads on a circuit substrate, in accordance with an embodiment of the invention; and

FIGS. 4A and 4B are schematic frontal views of matrices of dots of solder paste deposited on a circuit substrate in two successive process stages, in accordance with an embodiment of the invention.

### DETAILED DESCRIPTION OF EMBODIMENTS

### Overview

Soldering of electronic components is widely used in connecting solid electronic components to printed circuit boards and other substrates. For this purpose, dots of solder paste are formed in appropriate locations on the substrate, for example by screen printing or dispensing. (Such dots of solder paste on a substrate are also referred to simply as solder dots, and the term “solder dots” should be understood in this sense in the present description and in the claims.) Then, after placement of the electronic components, a thermal process (known as “reflow”) transforms the solder paste into a solid conducting bond. Current trends in miniaturization of electronic devices, such as chip scale packaging (CSP), are driving a demand for smaller solder dot volume and increased dot deposition rate.

Embodiments of the present invention that are described herein address this need by providing novel methods and apparatus for LIFT-based deposition of solder dots on an acceptor substrate, such as an electronic circuit board. These methods are capable of printing existing, commercially-available solder pastes without modification, including pastes containing large particles of metal solder, with particle diameters greater than 10 μm, while creating solder dots as small as 200 μm in diameter. Furthermore, the present methods are able to deposit solder dots precisely and reliably even with the donor film at a large distance between from the surface of the acceptor substrate, for example at a distance of at least 200 μm, or even 500 μm or more. These large donor/acceptor distances are important in facilitating high-speed production of large arrays of solder dots.

The methods and apparatus for circuit fabrication that are described below use a donor sheet comprising a donor substrate, which is transparent in a specified spectral range, for example in the near-infrared range, with a donor film comprising a solder paste on one side of the donor substrate. To promote rapid, uniform ejection of the solder paste under laser irradiation, a sacrificial layer, which absorbs optical radiation within the specified spectral range, is disposed over the surface of the donor substrate, between the donor substrate and the donor film.

To print solder dots, the donor sheet is positioned so that the donor film is in proximity to a target location on the acceptor substrate. A pulsed laser beam in the specified spectral range passes through the opposite surface of the donor substrate and impinges on the sacrificial layer with a pulse energy and spot size selected so as to rapidly ablate the sacrificial layer. The explosive expansion of the sacrificial layer causes a viscoelastic jet of the solder paste to be ejected from the donor film and to deposit a solder dot at the target location on the acceptor substrate.

For effective jetting, it is advantageous that each laser pulse deliver a substantial dose of energy to the sacrificial layer. For this purpose, the spot size of the laser beam on the sacrificial layer is large, for example greater than 200 μm or even greater than 300 μm. In some embodiments, each laser pulse has an energy greater than 200 μJ, and possibly as much as 1 mJ or more, spread over a pulse duration that may range from 10 ns to 5 μs per pulse. To facilitate efficient energy transfer from an infrared laser beam to the sacrificial layer and thence to the solder paste, the sacrificial layer may advantageously comprise a thin film of an infrared-absorbing metal, such as a film of titanium, tungsten, chromium or molybdenum less than 100 nm thick. To reduce heat transfer away from the area of the laser spot, a donor substrate with low thermal conductivity, such as a polymer foil, may be used. Alternatively, other sorts of donor substrates, sacrificial layers, and corresponding laser parameters may be used, depending on application requirements.

By appropriate choice of the laser and donor parameters, the viscoelastic jets ejected from the donor film will deposit solder dots on the acceptor substrate with a dot diameter that is less than the spot size of the laser beam. For example, a laser spot size greater than 200 μm impinging on the sacrificial layer will give rise to deposition of solder dots of diameter less than 200 μm. These parameters differ from most LIFT systems that are known in the art, which use lasers with short (visible or ultraviolet) wavelength, short pulses, and small spot size to achieve precise deposition of molten droplets on the acceptor substrate. In contrast to such systems, the present embodiments enable the deposition of dots of solder paste and other rheological materials that are actually smaller than the laser spot size.

### System Description

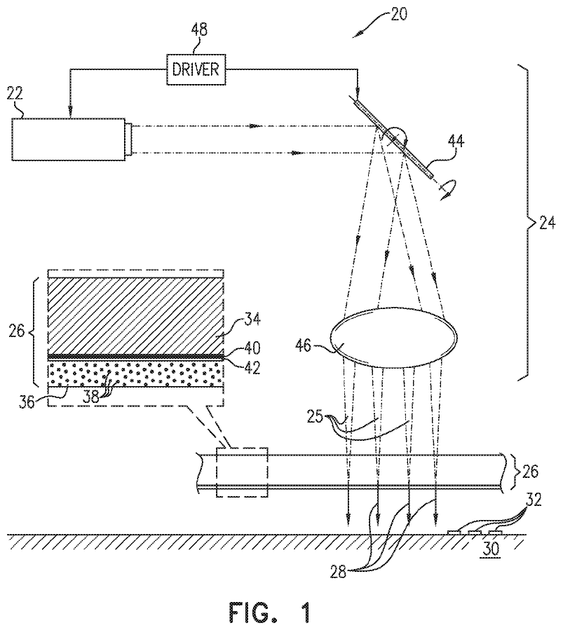

FIG. 1 is a schematic pictorial illustration of a system 20 for LIFT printing of solder pastes, in accordance with an embodiment of the invention. In system 20, a laser 22 outputs pulses of optical radiation. The term “optical radiation,” as used in the context of the present description and in the claims, refers to electromagnetic radiation in any of the visible, ultraviolet and infrared ranges, while “laser radiation” refers to optical radiation emitted by a laser. An optical assembly 24 directs the pulsed laser beam to pass through the upper surface of a donor sheet 26, which comprises a donor substrate 34 and a donor film 36 comprising a solder paste, as shown in the inset and described in further detail hereinbelow. Donor film 36 comprises metal solder particles 38, whose diameter varies and may be greater than 10 μm, depending on the type of solder paste. For example, donor film 36 may comprise type 4 solder paste, in which particles 38 have typical diameters between 20 and 30 μm, or other types of solder paste with finer particles.

Optical assembly 24 focuses the laser pulses into one or more beams 25, which impinge on a sacrificial layer 40 in donor sheet 26, between donor substrate 34 and donor film 36. The pulse energy and spot size of beams 25 are selected so as to ablate the sacrificial layer. This ablation causes viscoelastic jets 28 of solder paste to be ejected from donor film 36 and to deposit solder dots 32 at target locations on an acceptor substrate 30, such as a circuit board. Typically (although not necessarily), solder dots 32 have a diameter that is less than the spot size of laser beams 25 on sacrificial layer 40. In an example embodiment, the spot size of laser beams 25 impinging on sacrificial layer 40 is greater than 200 μm or even greater than 300 μm, while the diameter of solder dots 32 deposited by the resulting viscoelastic jets 28 is less than 200 μm.

To promote precise and reliable jetting of the solder paste in donor film 36, laser beams 25 comprise pulses with a duration between 10 ns and 5 μs per pulse, which impinge on sacrificial layer 40 with an energy greater than 200 μJ per pulse. These pulse parameters can be readily achieved by near-infrared lasers that are known in the art, such as fiber lasers. Such a laser may advantageously operate in a MOPA (master oscillator/power oscillator) configuration, which also enables flexible control over the pulse energy and duration. The pulse parameters can be optimized depending, inter alia, on the type of solder paste in donor film 36 and the sizes of solder dots 32 that are to be created.

Donor substrate 34 typically comprises a thin, flexible polymer foil, such as polyethylene terephthalate (PET), polyethylene terephthalate glycol (PETG), polyethylene naphthalate (PEN), polyimide (PI), polycarbonate (PC), or polypropylene (PP). Such materials are advantageous in being highly transparent at near infrared wavelengths, as well as having low thermal conductivity, for example κ<0.5 W/m*K. As a result of the low thermal conductivity, heat generated by the absorption of laser beams 25 in sacrificial layer 40 is applied more efficiently in generating viscoelastic jets 28, with minimal transverse dissipation through the donor substrate. Alternatively, however, donor substrate 34 may comprise a rigid sheet, made either of a polymer or an inorganic material, such as a suitable glass.

Donor substrate 34 is coated on the side facing toward acceptor substrate 30 with sacrificial layer 40, comprising a thin film with strong absorption at the infrared wavelength of laser 22. In some embodiments, sacrificial layer 40 comprises a metal film, such as a film of titanium, tungsten, chromium or molybdenum, or an alloy of these or other metals, with thickness less than 100 nm or even less than 50 nm. These metals are also advantageous in having a high melting temperature and can thus store more of the laser pulse energy prior to ablation, i.e., until they burst explosively. Donor film 36 is typically much thicker than sacrificial layer 40, for example with a donor film thickness of about 50 μm.

As sacrificial layer 40 bursts under laser irradiation, it propels a corresponding jet 28 forward toward acceptor substrate 30. The thin sacrificial layer efficiently transforms the absorbed laser energy into thrust, which propels the jet of solder paste uniformly in the forward direction over a substantial distance, typically 500 μm or more. A thicker sacrificial layer can increase the energy required for ablation without improving the quality of jetting. Considering the small volume of the sacrificial material in layer 40 relative to the solder paste in donor film 36, and the location of the sacrificial layer on the inner side of the donor film, solder dots 32 contain little or no contamination due to the sacrificial layer.

The use of sacrificial layer 40 in donor sheet 26 ensures efficient, uniform jetting of the solder paste in donor film 36. In the absence of the sacrificial layer, the large size of particles 38 in the solder paste would cause scattering and nonuniform absorption of the laser energy, and the resulting jets of solder paste could consequently be unstable. Sacrificial layers of this sort can be useful not only in deposition of solder paste, but also in LIFT jetting of other rheological materials, particularly polymers and other compounds with low optical absorption at laser wavelengths, such as adhesives, inks and pastes.

When additional protection from contamination of the solder paste is desired, donor sheet 26 may optionally comprise a polymeric protective layer 42 between the metal film of sacrificial layer 40 and donor film 36, as shown in the inset in FIG. 1. Protective layer 42 comprises a thin layer of elastic material, for example polyimide or silicone, with thickness between about 3 and 20 μm and Young's modulus in the range of about 10 MPa to 5 GPa. Alternatively, other materials and parameters may be used. Proper choice of protective layer 42 can both eliminate contamination of the solder paste and improve the stability of jet formation.

Optical assembly 24 comprises a beam deflector 44 and scan lens optics 46, which direct a pulsed beam 25 of radiation from laser 22 to pass through the upper surface of donor substrate 34 and thus impinge on sacrificial layer 40. Optical assembly 24 directs beam 25 in a spatial pattern determined by a driver 48. Driver 48 typically comprises a general-purpose computer or special-purpose microcontroller, which has suitable interfaces to the other elements of system 20 and which is driven in software to perform the functions that are described herein. Program instructions implementing methods such as those described herein may be transmitted over or stored on carrier medium. The carrier medium may include a storage medium such as a read-only memory, a random access memory, a magnetic or optical disk, a non-volatile memory, a solid state memory, a magnetic tape, and the like.

In the pictured embodiment, beam 25 is scanned by deflector 44 so as to impinge on an array of points on sacrificial layer 40 and thus to deposit a corresponding matrix of solder dots 32 on acceptor substrate 30. Deflector 44 in the pictured embodiment comprises a dual-axis scanning mirror, which scans the laser pulses sequentially over the array of points. Alternatively, deflector 44 may comprise a pair of single-axis scanning mirrors, typically with orthogonal scan axes. These mirrors may be scanned by galvanometers or any other suitable sort of scanning mechanisms that are known in the art. Each pulse of beam 25 causes a corresponding jet 28 of solder paste to be ejected from donor film 36 onto a corresponding target location on acceptor substrate 30. As noted above, because jets 28 are ejected from donor film 36 in a direction perpendicular to donor substrate 34 and at high speed, donor sheet 26 may be positioned at a moderate distance from acceptor substrate 30, for example with a spacing of 0.5 mm, or even as much as 1 mm, between donor film 36 and acceptor substrate 30.

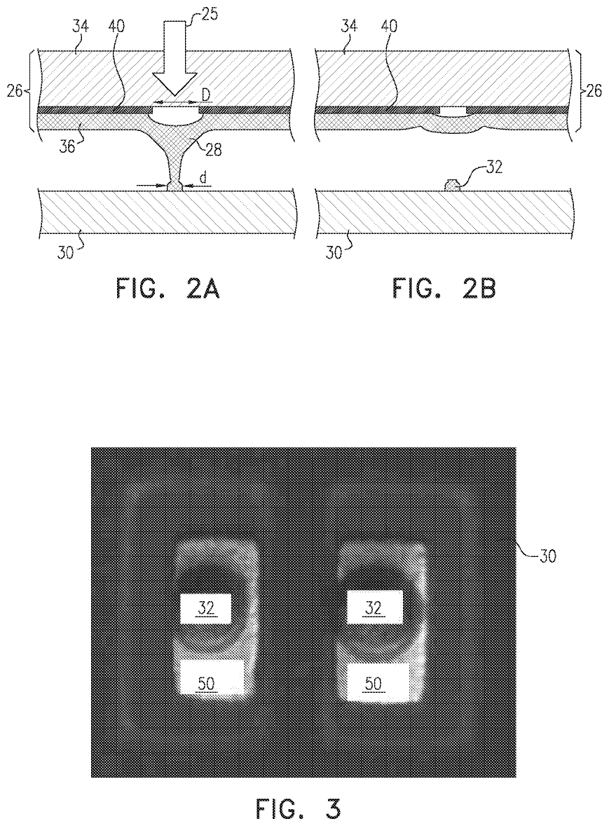

In an alternative embodiment, beam deflector 44 comprises an acousto-optic modulator. The acousto-optic modulator could operate as a single-axis deflector in conjunction with a scanning mirror with an orthogonal scan axis; or alternatively, the scanning functions of deflector 44 may be carried out by a two-dimensional acousto-optic deflector. Acousto-optic modulators of this sort are shown, for example, in FIG. 2A or 2B of the above-mentioned U.S. Pat. No. 9,925,797 and described in detail in columns 7-8 of this patent, and further description is beyond the scope of the present disclosure. Driver 48 drives laser 22 to output a train of pulses of suitable wavelength, duration and energy, while driving beam deflector 44 to split and steer laser beams 25. In this configuration, laser 22 and optical assembly cause ejection of multiple jets 28 of solder paste from donor film 36 concurrently onto specified target locations on acceptor substrate 30.

In some embodiments, system 20 also comprises a positioning assembly (not shown in the figures), which may comprise an X-Y stage, for example, on which acceptor substrate 30 is mounted. The positioning assembly shifts acceptor substrate 30 relative to optical assembly 24 and donor sheet 26 so as to deposit solder dots 32 at different target locations across the surface of the acceptor substrate. Additionally or alternatively, the positioning assembly may comprise motion components that shift optical assembly 24, as well as donor sheet 26, over the surface of the acceptor substrate.

### Details of Solder Dot Formation

FIGS. 2A and 2B are schematic sectional views showing details of the process of deposition of solder dot 32 on acceptor substrate 30, in accordance with an embodiment of the invention. FIG. 2A shows jet 28 of solder paste being ejected from donor film 36 in a LIFT process, while FIG. 2B shows dot 32 and donor sheet 26 after the process is completed.

As can be seen in FIG. 2A, the spot size D of laser beam 25 on sacrificial layer 40 is larger than the diameter d of solder dot 32. The laser spot size D is expressed, for example, in terms of the full width at half maximum (FWHM) of the laser beam intensity. At the stage shown in FIG. 2A, the part of sacrificial layer 40 irradiated by beam 25 has been vaporized explosively, giving rise to a bubble of gas that drives jet 28 downward toward acceptor substrate 30. Due to the high viscosity of the solder paste, jet 28 tends to narrow as it extends away from donor substrate 34, while drawing in solder paste from the surrounding area of donor film 36.

When jet 28 contacts acceptor substrate 30, dot 32 breaks off and adheres to the substrate, as shown in FIG. 2B. The remaining solder paste in the jet is drawn elastically back toward donor substrate 34. As noted earlier, solder dots 32 can be produced in this manner with a diameter d<200 μm, while donor film 36 is held at a distance of 500 μm from acceptor substrate 30. These dimensions can be varied by changing the parameters of donor sheet 26 and laser beam 25.

FIG. 3 is a photomicrograph showing solder dots 32 deposited on metal pads 50 on acceptor substrate 30, in accordance with an embodiment of the invention. These solder dots were deposited using the techniques described above. Dots 32 in this case have diameters of about 180 μm and are printed about 160 μm apart (edge to edge). Because jets 28 are wider than the resulting dots 32, it may not be possible to print such closely-spaced dots concurrently or in immediate succession.

In this case, system 20 will print the dots sequentially, with a certain delay due to the time required for one solder dot to form and optical assembly 24 to shift to the next dot position (and possibly to shift donor sheet 26, as well). Using mechanically-scanner mirrors, as in FIG. 1, single laser beam 25 can reach a throughput of about 1000 solder dots per second in this manner, or possibly higher. The solder dots may be printed on a uniform raster, or they may alternatively be printed according to a random-access deposition plan, under the control of driver 48.

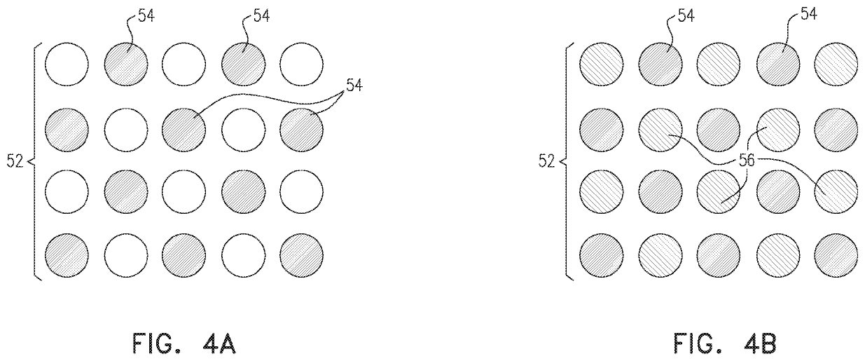

FIGS. 4A and 4B are schematic frontal views of a grid 52 of solder dots 54, 56, which are deposited on a circuit substrate in two successive process stages, in accordance with an embodiment of the invention. In this embodiment, an array of pulsed laser beams 25 impinge simultaneously at respective points on the sacrificial layer of donor sheet 26, and thus deposit a first matrix of solder dots 54 on the acceptor substrate, as shown in FIG. 4A. Alternatively, solder dots 54 may be produced sequentially, using a single, scanning laser beam. In either case, solder dots 54 are spaced sufficiently far apart so that the respective jets 28 can be ejected simultaneously or successively from donor film 36 without interfering with one another.

After depositing solder dots 54, donor sheet 26 is shifted, and optical assembly 24 directs the laser beam or beams 25 to irradiate corresponding locations on the sacrificial layer in order to deposit a second matrix of solder dots 56. These latter solder dots 56 are offset and interleaved with the first matrix of solder dots 54 on the acceptor substrate. Thus, the full grid 52 of closely-spaced solder dots 54 and 56 is formed in only two process steps. This approach can be used, for example, in depositing solder dots on closely-spaced arrays of contact pads on a circuit board, as are used in mounting integrated circuits.

Alternatively, other patterns of solder dots can be produced in two or more process steps, with appropriate motion of donor sheet 26 between the steps as required. Optimal fabrication plans, in terms of throughput and efficient use of donor material, can be developed depending on the contact pad layout in each case.

Although the embodiments described above refer specifically to solder pastes, the principles of the present invention may similarly be applied, mutatis mutandis, in LIFT printing of pastes of other kinds. The present techniques are particularly advantageous, as explained above, in printing pastes that contain large particles, for example pastes containing ceramic particles.

It will thus be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. A method for fabrication, comprising:
providing a donor sheet comprising:
a donor substrate, which is transparent in a specified spectral range and has opposing first and second surfaces;
a sacrificial layer, which absorbs optical radiation within the specified spectral range and is disposed over the first surface of the donor substrate; and
a donor film, which comprises a paste and is disposed over the sacrificial layer on the donor substrate;
positioning the donor sheet so that the donor film is in proximity to a target location on an acceptor substrate;
directing a pulsed laser beam in the specified spectral range to pass through the second surface of the donor substrate and impinge on the sacrificial layer with a pulse energy and spot size selected so as to ablate the sacrificial layer, thus causing a viscoelastic jet of the paste to be ejected from the donor film and to deposit, at the target location on the acceptor substrate, a dot having a diameter less than the spot size of the laser beam.

2. The method according to claim 1, wherein the donor substrate comprises a polymer foil.

3. The method according to claim 2, wherein the polymer foil has a thermal conductivity κ<0.5 W/m*K.

4. The method according to claim 1, wherein the sacrificial layer comprises a metal film.

5. The method according to claim 4, wherein the donor sheet comprises a polymeric protective layer between the metal film and the donor film.

6. The method according to claim 4, wherein the metal film has a thickness less than 100 nm and comprises a metal selected from a group consisting of titanium, tungsten, chromium and molybdenum.

7. The method according to claim 1, wherein the paste is a solder paste.

8. The method according to claim 7, wherein the solder paste comprises metal particles having a diameter greater than 10 μm.

9. The method according to claim 8, wherein the diameter of the dot formed by the viscoelastic jet is less than 200 μm.

10. The method according to claim 1, wherein positioning the donor sheet comprises holding the donor film at a distance of at least 200 μm from a surface of the acceptor substrate.

11. The method according to claim 10, wherein the distance is at least 500 μm.

12. The method according to claim 1, wherein directing the pulsed laser beam comprises directing infrared laser radiation to impinge on the sacrificial layer.

13. The method according to claim 1, wherein directing the pulsed laser beam comprises directing one or more pulses to impinge on the sacrificial layer with an energy greater than 200 μJ per pulse.

14. The method according to claim 13, wherein the one or more pulses have a duration between ns and 5 μs per pulse.

15. The method according to claim 1, wherein the spot size of the laser beam impinging on the sacrificial layer is greater than 200 μm, and the diameter of the dot deposited by the viscoelastic jet is less than 200 μm.

16. The method according to claim 15, wherein the spot size of the laser beam impinging on the sacrificial layer is greater than 300 μm.

17. The method according to claim 1, wherein directing the pulsed laser beam comprises directing an array of pulsed laser beams to impinge simultaneously at respective points on the sacrificial layer, so as to deposit a corresponding matrix of dots on the acceptor substrate.

18. The method according to claim 17, wherein directing the array of pulsed laser beams comprises depositing a first matrix of the dots on the acceptor substrate, and then shifting the donor sheet and directing the array of the pulsed laser beams to deposit a second matrix of the dots, interleaved with the first matrix of the dots on the acceptor substrate.

19. Apparatus for fabrication, comprising:
a donor sheet comprising:
a donor substrate, which is transparent in a specified spectral range and has opposing first and second surfaces;
a sacrificial layer, which absorbs optical radiation within the specified spectral range and is disposed over the first surface of the donor substrate; and
a donor film, which comprises a paste and is disposed over the sacrificial layer on the donor substrate,
wherein the donor sheet is positioned so that the donor film is in proximity to a target location on an acceptor substrate;
a laser, configured to output a pulsed laser beam in the specified spectral range; and
an optical assembly, configured to direct the pulsed laser beam to pass through the second surface of the donor substrate and impinge on the sacrificial layer with a pulse energy and spot size selected so as to ablate the sacrificial layer, thus causing a viscoelastic jet of the paste to be ejected from the donor film and to deposit, at the target location on the acceptor substrate, a dot having a diameter less than the spot size of the laser beam.

20. The apparatus according to claim 19, wherein the donor substrate comprises a polymer foil, and wherein the polymer foil has a thermal conductivity κ<0.5 W/m*K.

21. The apparatus according to claim 19, wherein the sacrificial layer comprises a metal film, and wherein the metal film has a thickness less than 100 nm and comprises a metal selected from a group consisting of titanium, tungsten, chromium and molybdenum.

22. The apparatus according to claim 19, wherein the paste is a solder paste, and wherein the solder paste comprises metal particles having a diameter greater than 10 μm.

23. The apparatus according to claim 19, wherein the donor sheet is positioned at a distance of at least 200 μm from a surface of the acceptor substrate.

24. The apparatus according to claim 19, wherein the specified spectral range comprises an infrared wavelength range.

25. The apparatus according to claim 19, wherein the laser and the optical assembly are configured to direct one or more pulses of laser radiation to impinge on the sacrificial layer with an energy greater than 200 μJ per pulse.

26. The apparatus according to claim 25, wherein the one or more pulses have a duration between 10 ns and 5 μs per pulse.

27. The apparatus according to claim 19, wherein the spot size of the laser beam impinging on the sacrificial layer is greater than 200 μm, and the diameter of the solder dot deposited by the viscoelastic jet is less than 200 μm.

28. The apparatus according to claim 27, wherein the spot size of the laser beam impinging on the sacrificial layer is greater than 300 μm.

29. The apparatus according to claim 19, wherein the optical assembly is configured to direct an array of pulsed laser beams to impinge simultaneously at respective points on the sacrificial layer, so as to deposit a corresponding matrix of dots on the acceptor substrate.

30. The apparatus according to claim 29, wherein the array of pulsed laser beams causes a first matrix of the dots to be deposited on the acceptor substrate, after which the donor sheet is shifted, and the optical assembly directs the array of the pulsed laser beams to deposit a second matrix of the dots, interleaved with the first matrix of the dots on the acceptor substrate.
